(19) United States
(12) Patent Application Publication
(10) Pub. No.: US 2010/0065811 A1
(43) Pub. Date: Mar. 18, 2010

(54) SINGLE PHOTON SOURCE WITH AllnN CURRENT INJECTION LAYER

(76) Inventors: Mathieu Xavier SENES, Oxford (GB); Katherine Louise SMITH, Oxford (GB); Victoria Broadley, Oxon (GB); Stewart Edward HOOPER, Oxford (GB)

Correspondence Address: MARK D. SARALINO ( SHARP );RENNER, OTTO, BOISSELLE & SKLAR, LLP, 1621 EUCLID AVENUE, 19TH FLOOR, CLEVELAND, OH, 44115, US

(21) Appl. No.: 12/212,729

(22) Filed: Sep. 18, 2008

(51) Int. Cl. H01L 33/00

(52) U.S. Cl. 257/13; 257/E33.008

(57) ABSTRACT

A photon source includes a substrate, an active region formed above the substrate, and a pair of electrodes configured to provide an injection current which passes through the active region. The active region includes a quantum dot layer including one or more Al_{y}GaₓIn_{1-x-y}N quantum dots, where 0≦x≦1 and 0≦y≦<1, and an AlInN current confinement layer adjacent the quantum dot layer. The current confinement layer has an aperture which defines a low resistance path for the injection current to flow through the active region between the pair of electrodes. The quantum dot layer includes less than 50 quantum dots within the aperture as projected onto the quantum dot layer.

### TECHNICAL FIELD

The present invention relates to the field of light emitting devices which are capable of emitting a predetermined number of photons at predetermined times, and more specifically which are capable of emitting a single photon on demand.

### BACKGROUND OF THE INVENTION

Quantum information in the form of quantum communications and quantum computing is currently an exceedingly active field. A single source that efficiently produces photons with antibunching characteristics or an entangled-pair of photons is one such pivotal hardware element for quantum information technology. Using a single photon source, secure quantum communication will prevent any potential eavesdropper from intercepting a message without the receiver noticing. Indeed, it works on the fact that measurement of a quantum state causes a disturbance which can be detected by the sender and the intended recipient of the bits.

There are four main possible sources for single photons; these are a single atom in a cavity (Rempe, PRL 2002), a single nitrogen vacancy in diamond (H. Weinfurter PRL 2000, Grangier PRL 2002), a single molecule at room temperature (B. Lounis and Moerner, Nature 2000), and a single quantum dot. But the first three sources require optical excitation of carriers using an external laser source, which is cumbersome and expensive. However, semiconductor quantum dots can be easily incorporated in an electric device for electrical injection of the carriers.

Electrically injected single photon emitters have been demonstrated by D. J. P. Ellis et al in Appl. Phys. Lett. 88, 133509 (2006) based upon a quantum dot structure with an aperture in an insulating oxide layer to restrict current injection into a single quantum dot. However, the device used self-assembled InAs quantum dots, thus limiting the working temperature to 10-100° K. Moreover, an annulus of insulating aluminium oxide was used to limit the current injection to a single quantum dot. But uniformity control of the oxidation process is known as an issue which can result to current apertures with different dimensions over the wafer, leading to poor manufacturing yield. Other art which is principally of interest in that it deals with single photon source is U.S. Pat. No. 6,864,501 issued on Apr. 9, 2003, to Shields.

However, the main obstacle for commonly used epitaxially grown III-V quantum dots as single photon devices, such as InAs quantum dots, is the requirement of liquid helium cryogenic temperatures. II-VI materials have been investigated for overcoming this problem, such as CdSe/ZnS quantum dots. But the quantum efficiency and multi-phonon reduction efficiency at high temperatures were low.

Nitride quantum dots could allow for high-temperature operation because of strong quantum confinement effects, large optical-phonon energies and large exciton binding energies.

For example, S. Kako et al., Nature material vol. 5, p 887, November 2006, observed single quantum dot emission up to 250° K. However, they used optical excitation. Electrical injection of the carriers is preferred for practical devices.

Finally, it can be noted that Castiglia et al., Appl. Phys. Lett. 90, 033514, 2007, described the use of an oxidised AlInN interlayer lattice-matched to GaN to confine the injected current in an InGaN light emitting diode. However, the AlInN was oxidised to be insulating, and there was no mention about using quantum dots in the active region, which is essential for getting single photon emission.

Though there have been many demonstrations of single photon sources using quantum dots with electrical injection of the carriers, they all required liquid-helium cryogenic temperatures, which is the main obstacle for industrial application.

### SUMMARY OF THE INVENTION

So it is an object of the present invention to address the above problems, by providing a single photon source with high efficiency working at room temperature or temperatures easily reachable with thermo-electric cooling.

In accordance with the principles of the present invention, a new class of single photon sources with electrical injection is provided which offers the possibility of room temperature or easily reachable thermoelectric cooling temperature operation.

This advantage is realised by using epitaxial nitride quantum dots which provide strong confinement to the carriers. Single photon emission is achieved by restricting the injected current to a single quantum dot. It is proposed to use a layer of single crystal AlInN, the AlInN layer having one aperture such that the dimension of the aperture is tailored to the density of the quantum dots in order to restrict the current injection to a single quantum dot.

Moreover, the use of high resistance layer of AlInN avoids the need to oxidise the AlInN layer in order to increase its electrical resistance, and avoids the disadvantages mentioned above.

Thus it is an object of the present invention to produce a new class of single photon source which is capable of emitting predetermined number of photons at predetermined times at room temperature or for temperatures easily reachable with thermo-electric cooling (e.g. above 200° K). These and other objects, features and advantages of the invention will be apparent from the following more particular description of preferred embodiments of the invention, as illustrated in the accompanying drawings.

According to an aspect of the invention, a photon source includes a substrate, an active region formed above the substrate, and a pair of electrodes configured to provide an injection current which passes through the active region. The active region includes a quantum dot layer including one or more Al_{y}GaₓIn_{1-x-y}N quantum dots, where 0≦x≦1 and 0≦y≦1, and an AlInN current confinement layer adjacent the quantum dot layer. The current confinement layer has an aperture which defines a low resistance path for the injection current to flow through the active region between the pair of electrodes. The quantum dot layer includes less than 50 quantum dots within the aperture as projected onto the quantum dot layer.

According to another aspect, the quantum dot layer includes less than 10 quantum dots within the aperture as projected onto the quantum dot layer.

In accordance with another aspect, the quantum dot layer includes only a single quantum dot within the aperture as projected onto the quantum dot layer.

According to still another aspect, the one or more quantum dots are epitaxial nitride quantum dots.

According to yet another aspect, the one or more quantum dots have a maximum dimension of less than 50 nm.

In still another aspect, the one or more quantum dots have a height between 1 nm and 5 nm.

With regard to another aspect, the current confinement layer has a resistivity greater than 1·10² Ω·cm.

In yet another aspect, the current confinement layer has a resistivity greater than 1·10⁴ Ω·cm.

According to another aspect, the current confinement layer has an In ratio between 0.15 and 0.2.

According to still another aspect, the current confinement layer has an In ratio of approximately 0.18 so as to maintain a small lattice mismatch to GaN.

In accordance with another aspect, the current confinement layer is a single crystal AlInN layer.

According to another aspect, a capping layer disposed on the quantum dot layer is provided, the band gap of the capping layer being higher than the band gap of the one or more quantum dots.

In accordance with another aspect, the current confinement layer and the capping layer are formed on a same side of the quantum dot layer.

According to another aspect, the current confinement layer and the capping layer are formed on opposite sides of the quantum dot layer.

In accordance with yet another aspect, a photon source includes a substrate, a buffer layer formed on the substrate, and a mesa structure formed on the buffer layer. The mesa structure includes an active region with a quantum dot layer including one or more Al_{y}GaₓIn_{1-x-y}N quantum dots, where 0≦x≦1 and 0≦y≦1, a capping layer disposed on the quantum dot layer, the band gap of the capping layer being higher than the band gap of the one or more quantum dots, and an AlInN current confinement layer adjacent the quantum dot layer, the current confinement layer having an aperture which defines a low resistance path for the injection current to flow through the active region, wherein the quantum dot layer includes less than 50 quantum dots within the aperture as projected onto the quantum dot layer.

According to another aspect, the mesa defines the area of the quantum dot layer.

In accordance with another aspect, the mesa is circular.

According to another aspect, the diameter of the mesa is within the range of 1 μm to 20 μm.

To the accomplishment of the foregoing and related ends, the invention, then, comprises the features hereinafter fully described and particularly pointed out in the claims. The following description and the annexed drawings set forth in detail certain illustrative embodiments of the invention. These embodiments are indicative, however, of but a few of the various ways in which the principles of the invention may be employed. Other objects, advantages and novel features of the invention will become apparent from the following detailed description of the invention when considered in conjunction with the drawings.

### BRIEF DESCRIPTION OF THE DRAWINGS

FIG. 1 is a sectional view showing a nitride single photon emitting device according to a first embodiment of the invention.

FIG. 2 is a sectional view showing the active region of the single photon emitting device containing a layer of (Al,In,Ga)N quantum dots and a AlInN current confinement layer with an aperture.

FIG. 3 is a sectional view showing a nitride single photon emitting device according to a second embodiment of the invention.

### DETAILED DESCRIPTION OF THE INVENTION

The preferred embodiments of the invention will be described with reference of the drawings.

A device of the present invention may be grown by any suitable means and on any suitable substrate, which include but is not limited to any orientation of: sapphire, GaN or SiC.

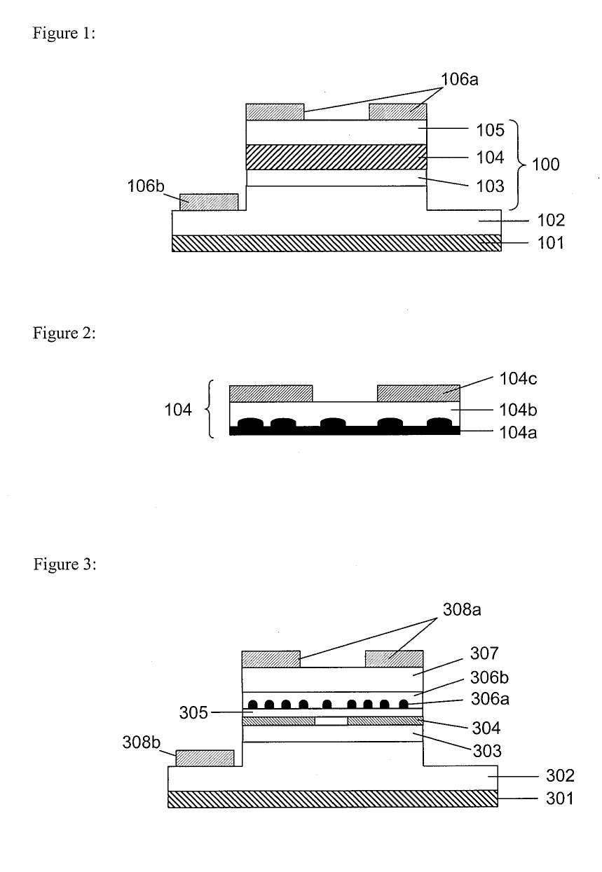

The first embodiment of the present invention is described with reference to FIG. 1. According to the first embodiment of this invention, FIG. 1 shows a schematic of a single photon emitting device fabricated in the (Al,In,Ga)N material system. The single photon emitting device of FIG. 1 may contain a sapphire substrate 101. An n-type buffer layer 102 made in the (Al,In,Ga)N material system, and preferentially in the (Al,Ga)N material system may be disposed on top of the substrate 101. A non-intentionally doped (Al,Ga)N layer 103 may be disposed on top of the buffer layer 102 to improve injection efficiency of the carriers. The active region 104 is then disposed on top of the layer 103. A p-type (Al,Ga)N layer 105 may be disposed on top of the active region 104. On the top surface of the contact layer 105 is a p-electrode 106a and on the rear surface of the buffer layer 102 is an n-electrode 106b.

The single photon light emitting device of FIG. 1 may contain an active region 104 shown also in FIG. 2. The active region may comprise Al_{y}GaₓIn_{1-x-y}N quantum dots 104a disposed on layer 103. The Al_{y}GaₓIn_{1-x-y}N quantum dots 104a may have the composition wherein 0≦x≦1 and 0≦y≦1, such that they may be comprised from GaN, InN, InGaN, and AlGaInN. The quantum dots 104a may have the size wherein all three dimensions are each less than 50 nanometers (nm). The quantum dots 104a may have a size wherein the height is less than 12 nm. The quantum dots 104a may preferably have a height between 1 nm and 5 nm.

The quantum dots 104a may be not intentionally doped.

An Al_{y}GaₓIn_{1-x-y}N capping layer 104b may be disposed on top of the quantum dots 104a. The Al_{y}GaₓIn_{1-x-y}N capping layer 104b may have a composition wherein 0≦x≦1 and 0≦y>1, such that the band gap of the Al_{y}GaₓIn_{1-x-y}N capping layer 104b is higher than the band gap of the quantum dots 104a.

The capping layer 104b may have a thickness between 1 nm and 100 nm. The capping layer 104b may have a thickness between 1 nm and 10 nm. Preferably, the capping layer 104b is not intentionally doped or may be p-type doped or n-type doped. In this embodiment, the capping layer 104b is preferably not intentionally doped.

According to the invention, an AlInN layer 104c is provided on top of the capping layer 104b to act as a current confinement layer. The AlInN layer 104c has one aperture defined therethrough, to provide a low resistance path for current to flow between the upper electrode 106a and the lower electrode 106b. The AlInN preferably has a resistivity higher than 1·10² ohm centimeter (Ω·cm) and preferably has a resistivity higher than 1·10⁴ Ω·cm.

In this embodiment, the AlInN current confinement layer 104c may have one aperture such that only a few quantum dots are present under the aperture. Preferably, the number of quantum dots under the aperture is less than 50. Preferably, the number of quantum dots under the aperture is 1. For example, if the quantum dot density of the quantum dot layer 104a is 1·10¹⁰ cm⁻², a circular aperture size of the AlInN layer 104c may have a diameter which is not exceeding 350 nm, i.e. less than 10 quantum dots are present under the aperture, and preferably have a diameter which is around 110 nm, i.e. only 1 quantum dot is present under the aperture.

The aperture size in the AlInN layer 104c is function of the quantum dot density. In order to have only one quantum dot under the aperture, the aperture size can be calculated function to the quantum dot density d as follow: for a square aperture with a side size a, a=squareroot (1/d). For a circular aperture of diameter D, D=2×squareroot (1/(pi×d)).

The current confinement layer 104c is preferably made of AlInN having an In ratio between 0.15 (or In content close to 15%) and 0.2 (20%), and preferably having an In ratio of 0.18 (18%) in order to maintain a small lattice mismatch to GaN.

A mesa structure 100 is preferably formed. The mesa 100 defines the area of the quantum dot layer. The mesa 100 can be up to 100 micrometers (μm) in diameter, but the preferred diameter is 1-20 μm. A circular mesa is preferred, but alternatively the mesa may take any geometrical shape.

Mention is next made of an operation of the present invention.

When a voltage is applied between the two electrodes 106a and 106b, electrons and holes travel across the active region. Because of the aperture in the AlInN current confinement layer 104c, electrons and holes travel only across one quantum dot or a very limited number of quantum dots in the active region 100.

At low injection currents, the quantum dot may capture no more than a single electron and a single hole. The single electron and the single hole form an exciton in the quantum dot. The radiative recombination of the electron-hole pair occurs on the timescale of the radiative lifetime. Once the photon is emitted, the quantum dot can capture another electron and another hole.

For higher injection currents, the quantum dot may capture two electron-hole pairs, which form a bi-exciton. The output spectrum of the quantum dot thus consists of two single lines emitting at two different energies. Moreover, for higher injection currents, the quantum dot may also capture two electrons and a single hole, or two holes and a single electron. In this case, the output spectrum of the quantum dot thus consists of a single line but emitting at a different energy than for the emission of a single electron-hole pair, due to the Coulomb interaction of the extra carrier with the recombining electron-hole pair. Moreover, more than one quantum dot may be present under the aperture of the AlInN current confinement layer 104c. In this case, the emission may exhibit extra spectral lines at different energies arising form the emission of different quantum dots.

Thus, in order to remove photons from the output emitting at unwanted emission energies, the single photon emitting device of the present invention may comprise spectral filtering. The filter may comprise a spectrometer such as a grating or prism spectrometer. An interference filter or a fibre optic device may also be used or any other suitable filtering devices. The filter means may be integral with the single photon emitting device body, or may not be integral with the single photon emitting device body.

FIG. 3 shows a cross-sectional structure of a single photon emitting device according to a second embodiment of the present invention. The structure of the single photon emitting device of the present embodiment is similar to the one of the first embodiment presented in FIG. 1. For example, the device includes a substrate 301, buffer layer 302, non-intentionally doped (Al,Ga)N layer 303, p-type contact layer 307 and electrodes 308a and 308b.

In the embodiment of FIG. 3, however, the AlInN current confinement layer 304 is located under the quantum dot active layer 306a and capping layer 306b, i.e. the AlInN layer 304 is placed on the side of the n-type doped region of the single photon emitting device of the present invention. A (Al,Ga,In)N layer 305 may be placed between the AlInN layer 304 and the quantum dot layer 306a. The (Al,Ga,In)N layer 305 may be preferentially undoped. The (Al,In,Ga)N layer 305 may have a thickness between 1 nm and 100 nm. The (Al,In,Ga)N layer 305 may have preferably a thickness between 1 nm and 10 nm.

Alternatively, two AlInN current confinement layers may be placed on each side of the quantum dot layer 306a, with their apertures being aligned vertically.

Although the invention has been shown and described with respect to certain preferred embodiments, it is obvious that equivalents and modifications will occur to others skilled in the art upon the reading and understanding of the specification. The present invention includes all such equivalents and modifications, and is limited only by the scope of the following claims.

1. A photon source, comprising:
a substrate;
an active region formed above the substrate; and
a pair of electrodes configured to provide an injection current which passes through the active region,
wherein the active region comprises:
a quantum dot layer including one or more Al_{y}GaₓIn_{1-x-y}N quantum dots, where 0≦x≦1 and 0≦y≦1; and
an AlInN current confinement layer adjacent the quantum dot layer, the current confinement layer having an aperture which defines a low resistance path for the injection current to flow through the active region between the pair of electrodes, wherein the quantum dot layer includes less than 50 quantum dots within the aperture as projected onto the quantum dot layer.

2. The photon source of claim 1, wherein the quantum dot layer includes less than 10 quantum dots within the aperture as projected onto the quantum dot layer.

3. The photon source of claim 1, wherein the quantum dot layer includes only a single quantum dot within the aperture as projected onto the quantum dot layer.

4. The photon source of claim 1, wherein the one or more quantum dots are epitaxial nitride quantum dots.

5. The photon source of claim 1, wherein the one or more quantum dots have a maximum dimension of less than 50 nm.

6. The photon source of claim 1, wherein the one or more quantum dots have a height between 1 nm and 5 nm.

7. The photon source of claim 1, wherein the current confinement layer has a resistivity greater than 1·10² Ω·cm.

8. The photon source of claim 1, wherein the current confinement layer has a resistivity greater than 1·10⁴ Ω·cm.

9. The photon source of claim 1, wherein the current confinement layer has an In ratio between 0.15 and 0.2.

10. The photon source of claim 1, wherein the current confinement layer has an In ratio of approximately 0.18 so as to maintain a small lattice mismatch to GaN.

11. The photon source of claim 1, wherein the current confinement layer is a single crystal AlInN layer.

12. The photon source of claim 1, comprising a capping layer disposed on the quantum dot layer, the band gap of the capping layer being higher than the band gap of the one or more quantum dots.

13. The photon source of claim 12, wherein the current confinement layer and the capping layer are formed on a same side of the quantum dot layer.

14. The photon source of claim 12, wherein the current confinement layer and the capping layer are formed on opposite sides of the quantum dot layer.

15. A photon source, comprising:
a substrate;
a buffer layer formed on the substrate;
a mesa structure formed on the buffer layer, the mesa structure including an active region comprising:
a quantum dot layer including one or more Al_{y}GaₓIn_{1-x-y}N quantum dots, where 0≦x≦1 and 0≦y≦1;
a capping layer disposed on the quantum dot layer, the band gap of the capping layer being higher than the band gap of the one or more quantum dots; and
an AlInN current confinement layer adjacent the quantum dot layer, the current confinement layer having an aperture which defines a low resistance path for the injection current to flow through the active region, wherein the quantum dot layer includes less than 50 quantum dots within the aperture as projected onto the quantum dot layer.

16. The photon source of claim 15, wherein the current confinement layer includes only a single aperture, and the quantum dot layer includes less than 10 quantum dots within the aperture as projected onto the quantum dot layer.

17. The photon source of claim 16, wherein the quantum dot layer includes only a single quantum dot within the aperture as projected onto the quantum dot layer.

18. The photon source of claim 15, wherein the mesa defines the area of the quantum dot layer.

19. The photon source of claim 18, wherein the mesa is circular.

20. The photon source of claim 19, wherein the diameter of the mesa is within the range of 1 μm to 20 μm.
